(19) United States
(12) Patent Application Publication
(10) Pub. No.: US 2025/0329650 A1
(43) Pub. Date: Oct. 23, 2025

(54) SEMICONDUCTOR DEVICE AND METHOD OF FABRICATING THE SAME

(71) Applicant: Samsung Electronics Co., Ltd., Suwon-si (KR)

(72) Inventors: Jinwoo Lee, Suwon-si (KR); Saehan Park, Suwon-si (KR); Sutae Kim, Suwon-si (KR); Yubo Qian, Suwon-si (KR)

(21) Appl. No.: 18/978,718

(22) Filed: Dec. 12, 2024

(30) Foreign Application Priority Data
Apr. 19, 2024 (KR) 10-2024-0052530

(51) Int. Cl. H01L 23/528; H01L 23/522

(52) U.S. Cl. CPC H01L 23/5286; H01L 23/5226; H01L 23/5283

(57) ABSTRACT

Disclosed is a semiconductor device including a power delivery network layer on a bottom surface of a substrate, a gate electrode on the substrate, a first source/drain pattern on the substrate and including first and second patterns spaced apart from each other with the gate electrode therebetween, a through via structure that extends into the substrate and electrically connects to the power delivery network layer, an upper conductive contact on the first pattern of the first source/drain pattern, an upper power line that extends on the through via structure and on the upper conductive contact, a backside power rail that extends along an extension direction of the upper power line and is on an opposite side of the first source/drain pattern from the upper power line, and a backside conductive structure between the backside power rail and the second pattern of the first source/drain pattern.

### CROSS-REFERENCE TO RELATED APPLICATION

This U.S. nonprovisional application claims priority under 35 U.S.C § 119 to Korean Patent Application No. 10-2024-0052530 filed on Apr. 19, 2024 in the Korean Intellectual Property Office, the disclosure of which is hereby incorporated by reference in its entirety.

### BACKGROUND

The present inventive concepts relate to a semiconductor device and a method of fabricating the same, and more particularly, to a semiconductor device including a field effect transistor and a method of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some embodiments of the present inventive concepts provide a semiconductor device whose power consumption and electrical properties are improved.

Some embodiments of inventive concepts provide a semiconductor device that is easy to design.

An object of the present inventive concepts is not limited to the mentioned above, and other objects which have not been mentioned above will be clearly understood to those skilled in the art from the following description.

According to some embodiments of the present inventive concepts, a semiconductor

device may include a power delivery network layer on a bottom surface of a substrate, a gate electrode on the substrate, a first source/drain pattern on the substrate, the first source/drain pattern including a first pattern and a second pattern that are spaced apart from each other with the gate electrode therebetween, a through via structure that extends into the substrate and is electrically connected to the power delivery network layer, an upper conductive contact on the first pattern of the first source/drain pattern, an upper power line that extends on the through via structure and on the upper conductive contact, a backside power rail that extends along an extension direction of the upper power line and is on an opposite side of the first source/drain pattern from the upper power line, and a backside conductive structure between the backside power rail and the second pattern of the first source/drain pattern.

According to some embodiments of the present inventive concepts, a semiconductor device may include a power delivery network layer on a bottom surface of a substrate, a gate electrode on the substrate, a first source/drain pattern on the substrate, the first source/drain pattern including a first pattern and a second pattern that are spaced apart from each other with the gate electrode therebetween, a through via structure that extends into the substrate and is electrically connected to the power delivery network layer, an upper conductive contact on the first pattern of the first source/drain pattern, a plurality of upper power lines, ones of which extend on the through via structure and/or on the upper conductive contact, the upper power lines are electrically connected to the through via structure and the upper conductive contact, a backside power rail that extends along an extension direction of the upper power lines and is on an opposite side of the first source/drain pattern from the upper power line, and a backside conductive structure between the backside power rail and the second pattern of the first source/drain pattern.

According to some embodiments of the present inventive concepts, a semiconductor device may include a power delivery network layer on a bottom surface of a substrate, a gate electrode on the substrate, a first source/drain pattern on the substrate, the first source/drain pattern including a first pattern and a second pattern that are spaced apart from each other with the gate electrode therebetween, a first channel pattern between the first pattern of the first source/drain pattern and the second pattern of the first source/drain pattern, the first channel pattern including a plurality of semiconductor patterns that are spaced apart from each other in a direction perpendicular to the substrate, a through via structure that extends into the substrate and electrically connected to the power delivery network layer, a plurality of upper conductive contacts on the first pattern of the first source/drain pattern, the plurality of upper conductive contacts are adjacent to one another in a first direction parallel to a top surface of the substrate, a plurality of upper power lines that extend along the first direction on the through via structure and on the upper conductive contacts and that electrically connect the through via structure and the upper conductive contacts, a backside power rail that extends along the first direction and is on an opposite side of the first source/drain pattern from the upper power line, and a backside conductive structure between the backside power rail and the second pattern of the first source/drain pattern.

### BRIEF DESCRIPTION OF DRAWINGS

FIG. 1 illustrates a plan view showing a semiconductor device according to some embodiments of the present inventive concepts.

FIGS. 2A, 2B, and 2C illustrate cross-sectional views respectively taken along lines A-A′, B-B′, and C-C′ of FIG. 1.

FIG. 3A illustrates a block diagram showing a semiconductor device that includes a power gating circuit according to some embodiments of the present inventive concepts.

FIG. 3B illustrates an enlarged view partially showing a configuration of FIG. 1.

FIG. 4 illustrates a plan view showing a semiconductor device according to some embodiments of the present inventive concepts.

FIGS. 5A and 5B illustrate cross-sectional views respectively taken along lines A-A′ and C-C′ of FIG. 4.

FIG. 6 illustrates a plan view showing a semiconductor device according to some embodiments of the present inventive concepts.

FIG. 7 illustrates a cross-sectional view taken along line B-B′ of FIG. 6.

FIGS. 8A, 8B, 9A, 9B, 10, 11A, 11B, 11C, 12A, 12B, and 12C illustrate cross-sectional views showing a method of fabricating a semiconductor device according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts.

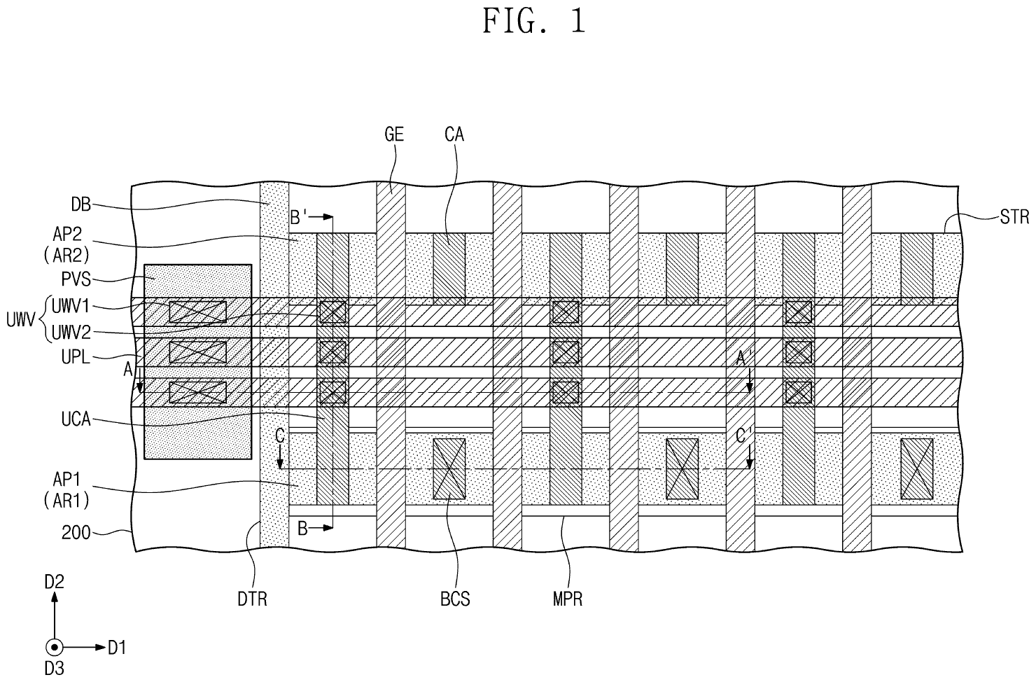

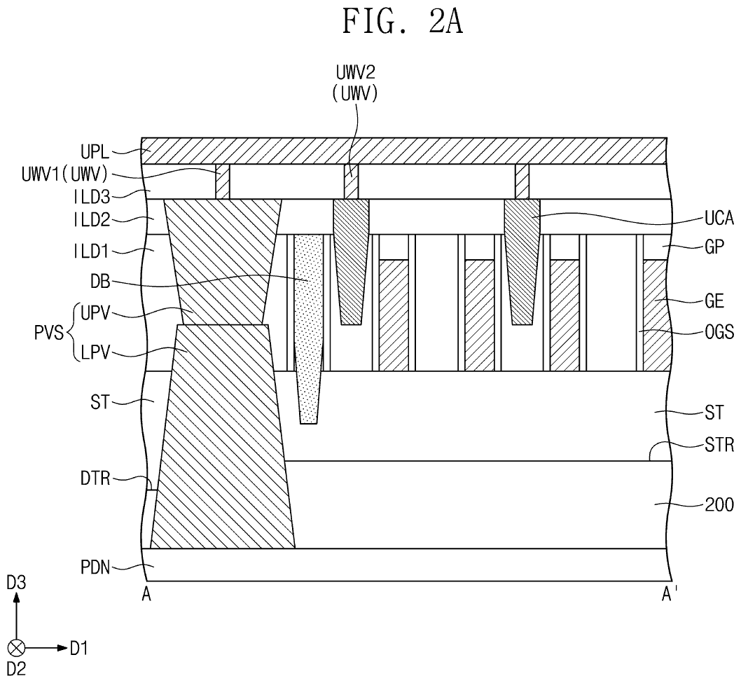

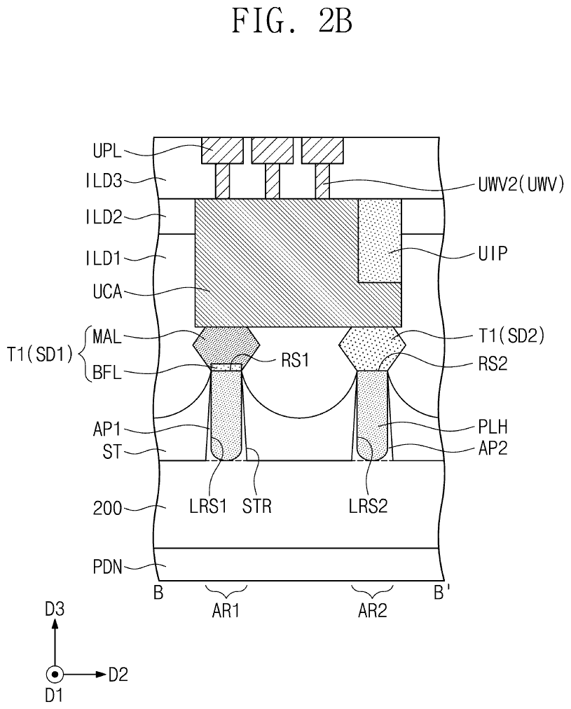

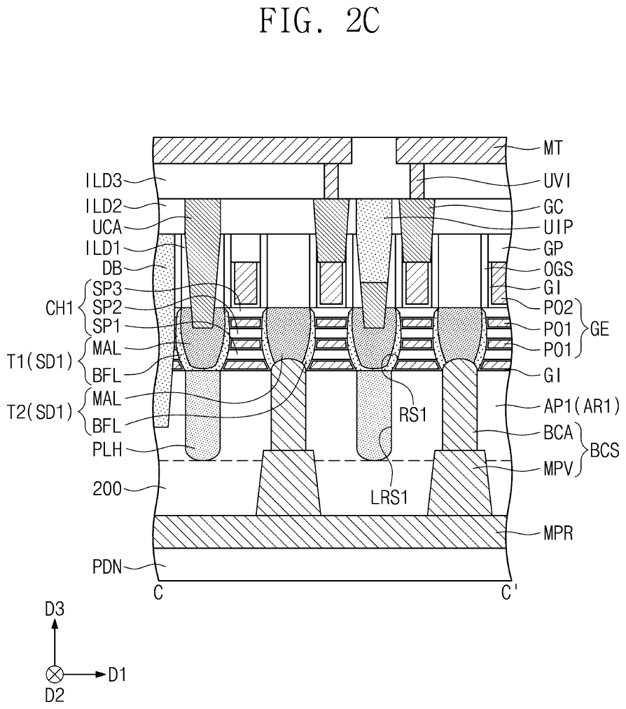

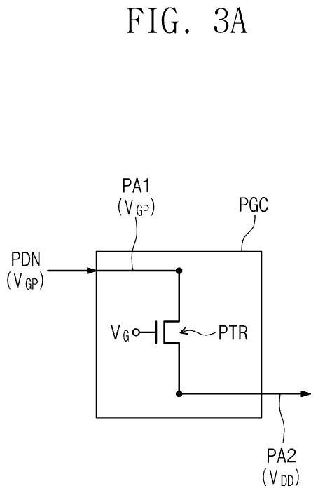

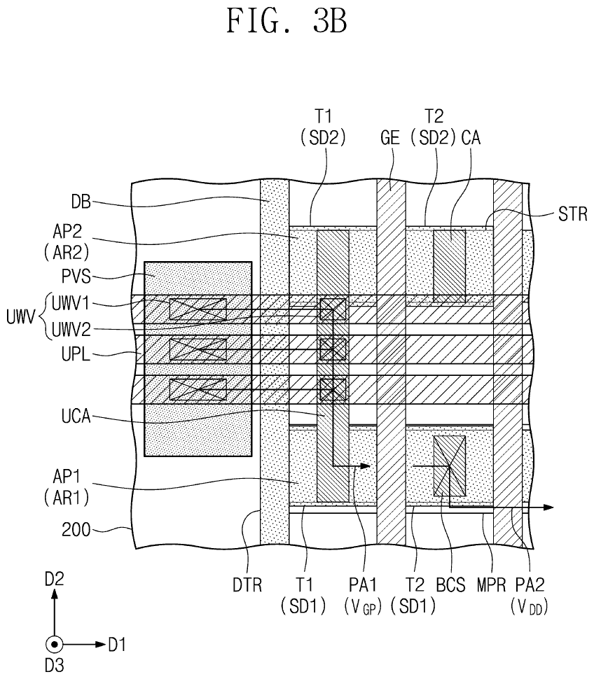

FIG. 1 illustrates a plan view showing a semiconductor device according to some embodiments of the present inventive concepts. FIGS. 2A, 2B, and 2C illustrate cross-sectional views respectively taken along lines A-A′, B-B′, and C-C′ of FIG. 1. FIG. 3A illustrates a block diagram showing a semiconductor device that includes a power gating circuit according to some embodiments of the present inventive concepts. FIG. 3B illustrates an enlarged view partially showing a configuration of FIG. 1.

Referring to FIGS. 1, 2A, 2B, and 2C, a substrate 200 may be provided which includes a single height cell (not shown). For example, the substrate 200 may include at least one selected from silicon (Si), germanium (Ge), silicon-germanium (SiGe), silicon oxide (SiO₂), silicon nitride (SiN), or silicon oxynitride (SiON). In this disclosure, each of the languages “A or B”, “at least one of A and B”, “at least one A or B”, “A, B, or C”, “at least one of A, B, and C”, and “at least one A, B, or C” may include one or any possible combination of elements listed in a corresponding one of the expressions mentioned above.

The single height cell may include one logic cell. In this disclosure, the logic cell may be a logic device (e.g., AND, OR, XOR, XNOR, and inverter) that performs a specific function. For example, the logic cell may include transistors of a logic device and wiring lines that connect the transistors to each other. For example, the single height cell may be one power gating cell which will be discussed below. A detailed description of the power gating cell will be further discussed below.

The single height cell may include a first active region AR1 and a second active region AR2 on the substrate 200. The first and second active regions AR1 and AR2 may extend in a first direction D1 and may be spaced apart from each other in a second direction D2. The first and second directions D1 and D2 may be parallel to a top surface of the substrate 200 and orthogonal to each other. For example, the first active region AR1 may be a PMOS region, and the second active region AR2 may be an NMOS region.

A first active pattern AP1 may be provided on the first active region AR1. A second active pattern AP2 may be provided on the second active region AR2. Each of the first and second active patterns AP1 and AP2 may be defined by a device isolation trench STR on an upper portion of the substrate 200. The first and second active patterns AP1 and AP2 may be a portion of the substrate 200. For example, the portion of the substrate 200 may protrude in a third direction D3. The third direction D3 may be perpendicular to the top surface of the substrate 200. For brevity of description, unless otherwise particularly stated, the substrate 200 may be defined to refer to another portion other than the protruding portion (e.g., the first and second active patterns AP1 and AP2) of the substrate 200. Each of the first and second active patterns AP1 and AP2 may extend in the first direction D1.

Although not shown, the first active pattern AP1 may include first active patterns that are spaced apart in the first direction D1 from each other across a substrate trench DTR, and likewise the second active pattern AP2 may include second active patterns that are spaced apart in the first direction from each other across a substrate trench DTR.

A device isolation pattern ST may be provided on the substrate 200, and may fill the device isolation trench STR and the substrate trench DTR. The device isolation pattern ST may surround the first and second active patterns AP1 and AP2. The device isolation pattern ST may include a dielectric material. For example, the device isolation pattern ST may include silicon oxide (SiO₂).

A first channel pattern CH1 may be provided on the first active pattern AP1, and a second channel pattern (not shown) may be provided on the second active pattern AP2. The first channel pattern CH1 may be provided in plural, and the plurality of first channel patterns CH1 may be spaced apart from each other in the first direction D1. The second channel pattern may be provided in plural, and the plurality of second channel patterns may be spaced apart from each other in the first direction D1. Each of the first channel pattern CH1 and the second channel pattern may include a first semiconductor pattern SP1, a second semiconductor pattern SP2, and a third semiconductor pattern SP3 that neighbor each other in the third direction D3, but the present inventive concepts are not limited thereto. For example, each of the first channel pattern CH1 and the second channel pattern may include four or more semiconductor patterns. For example, each of the first, second, and third semiconductor patterns SP1, SP2, and SP3 may include crystalline silicon.

First recesses RS1 may be defined between the first channel patterns CH1 that neighbor each other in the first direction D1. Second recesses RS2 may be defined between the second channel patterns that neighbor each other in the first direction D1.

A first source/drain pattern SD1 may be provided on the first active pattern AP1, and a second source/drain pattern SD2 may be provided on the second active pattern AP2. The first source/drain pattern SD1 may fill the first recess RS1, and the second source/drain pattern SD2 may fill the second recess RS2. Each of the first source/drain pattern SD1 and the second source/drain pattern SD2 may be connected to the first, second, and third semiconductor patterns SP1, SP2, and SP3. In this disclosure, the phrase “A and B are connected to each other” may include not only the meaning of “A and B are in direct contact with and connected to each other”, but also the meaning of “A and B are indirectly connected to each other through C (e.g., a conductive component).” The component C may be a singular component or a plurality of components. In other words, A and B may be electrically and/or physically connected to one another.

The first source/drain patterns SD1 may be impurity regions having a first conductivity type (e.g., p-type), and the second source/drain patterns SD2 may be impurity regions having a second conductivity type (e.g., n-type). For example, a pair of first source/drain patterns SD1 that neighbor in the first direction D1 may be connected through the first channel pattern CH1. For example, a pair of second source/drain patterns SD2 that neighbor in the first direction D1 may be connected through the second channel pattern.

The first source/drain patterns SD1 may include a semiconductor element (e.g., SiGe) whose lattice constant is greater than that of a semiconductor element of the first channel pattern CH1. Therefore, a pair of first source/drain patterns SD1 may provide the first channel pattern CH1 with a compressive stress. The second source/drain patterns SD2 may include the same semiconductor element (e.g., Si) as that of the second channel pattern.

The first source/drain pattern SD1 may include a buffer layer BFL that covers, overlaps, or is on an inner surface of the first recess RS1 and a main layer MAL that partially or completely fills most of a remaining unoccupied portion of the first recess RS1. For example, each of the buffer layer BFL and the main layer MAL may include silicon-germanium (SiGe). The buffer layer BFL may contain germanium (Ge) whose concentration is relatively low. The main layer MAL may contain germanium (Ge) whose concentration is relatively high. In some embodiments, the buffer layer BFL may contain only silicon (Si).

The first source/drain pattern SD1 may include a first pattern T1 electrically and/or physically connected to an upper conductive contact UCA which will be discussed below and a second pattern T2 connected to a backside conductive structure BCS which will be discussed below. The second source/drain pattern SD2 may include a first pattern T1 connected to an upper conductive contact UCA which will be discussed below and a second pattern T2 electrically and/or physically connected to an active contact CA which will be discussed below. The first pattern T1 and the second pattern T2 of each of the first and second source/drain patterns SD1 and SD2 may be spaced apart from each other with a gate electrode GE therebetween, which will be discussed below.

A first lower recess LRS1 may be provided below each of the first patterns T1 of the first source/drain patterns SD1. A second lower recess LRS2 may be provided below each of the first and second patterns T1 and T2 of the second source/drain patterns SD2. A sacrificial contact pattern PLH may fill each of the first lower recess LRS1 and the second lower recess LRS2. The sacrificial contact pattern PLH may include silicon-germanium (SiGe).

A gate electrode GE may be provided on and run across each of the first channel pattern CH1 and the second channel pattern. The gate electrode GE may be provided in plural. The plurality of gate electrodes GE may each extend in the second direction D2, and may be spaced apart from each other in the first direction D1.

The gate electrode GE may include an inner electrode PO1 and an outer electrode PO2. The inner electrode PO1 of the gate electrode GE may be provided between an uppermost semiconductor pattern SP3 of the plurality of semiconductor patterns SP1, SP2, and SP3 and the first and second active patterns AP1 and AP2. The outer electrode PO2 of the gate electrode GE may be provided on the uppermost semiconductor pattern SP3. The inner electrode PO1 of the gate electrode GE may include three electrode portions, but the present inventive concepts are not limited thereto. For example, the inner electrode PO1 of the gate electrode GE may include four or more electrode portions.

The gate electrode GE may include a first metal pattern and a second metal pattern on the first metal pattern. The first metal pattern may include a work-function metal that controls a threshold voltage of a transistor. For example, the first metal pattern may include at least one selected from metallic materials (e.g., Ti, Mo, W, Cu, Al, Ta, Ru, Ir, or Co) and metal nitrides (e.g., nitride of Ti, Mo, W, Cu, Al, Ta, Ru, Ir, or Co). The first metal pattern may further include carbon (C). The first metal pattern may include metallic materials having different work-function materials from each other.

The second metal pattern may include a metallic material (e.g., Ti, Mo, W, Cu, Al, Ta, Ru, Ir, or Co) whose resistance is less than that of the first metal pattern.

The inner electrode PO1 of the gate electrode GE may include a first metal pattern. The outer electrode PO2 of the gate electrode GE may include a first metal pattern and a second metal pattern.

A gate capping pattern GP may be provided on a top surface of the gate electrode GE. For example, the gate capping pattern GP may include at least one selected from SiON, SiCN, SiCON, or SiN.

Outer gate spacers OGS may be provided on lateral surfaces of the outer electrode PO2 of the gate electrode GE, and may extend onto lateral surfaces of the gate capping pattern GP. The outer gate spacer OGS may include a single layer or a multiple layer. For example, the outer gate spacer OGS may include at least one selected from SiON, SiCN, SiOCN, or SiN.

A gate dielectric pattern GI may be interposed between the gate electrode GE and the first, second, and third semiconductor patterns SP1, SP2, and SP3. The gate dielectric pattern GI may surround a top surface, a bottom surface, and opposite lateral surfaces of each of the first, second, and third semiconductor patterns SP1, SP2, and SP3. The gate dielectric pattern GI may cover, overlap, or be on a top surface of the device isolation pattern ST underneath the gate electrode GE. The gate dielectric pattern GI may be interposed between the outer electrode PO2 and the outer gate spacer OGS. For example, the gate dielectric pattern GI may include at least one selected from silicon oxide (SiO₂), silicon oxynitride (SiON), or high-k dielectric materials. In this disclosure, the high-k dielectric material may be defined to indicate a material whose dielectric constant is greater than that of silicon oxide.

A first interlayer dielectric layer ILD1 may be provided on the substrate 200. The first interlayer dielectric layer ILD1 may cover, overlap, or be on the outer gate spacers OGS and the first and second source/drain patterns SD1 and SD2. For example, the first interlayer dielectric layer ILD1 may have a top surface substantially the same level as that of a top surface of the gate capping pattern GP and that of a top surface of the outer gate spacer OGS.

On the first interlayer dielectric layer ILD1, a second interlayer dielectric layer ILD2 may cover, overlap, or be on the gate capping pattern GP. A third interlayer dielectric layer ILD3 may be provided on the second interlayer dielectric layer ILD2. For example, the first, second, and third interlayer dielectric layers ILD1, ILD2, and ILD3 may include silicon oxide (SiO₂).

An active contact CA may penetrate or extend in in the third direction D3 through or into the first and second interlayer dielectric layers ILD1 and ILD2. The active contact CA may be provided in plural, and each of the plurality of active contacts CA may have a lower portion buried in an upper portion of the second pattern T2 of the second source/drain pattern SD2. For example, the active contact CA may include at least one selected from metallic materials (e.g., Ti, Mo, W, Cu, Al, Ta, Ru, Ir, or Co), metal nitrides (e.g., nitride of Ti, Mo, W, Cu, Al, Ta, Ru, Ir, or Co), or metal silicides (e.g., silicide of Ti, Mo, W, Cu, Al, Ta, Ru, or Ir). The active contact CA may be connected to the second pattern T2 of the second source/drain pattern SD2.

Gate contacts GC may penetrate or extend in the third direction D3 through or into the second interlayer dielectric layer ILD2 and the gate capping pattern GP. Each of the gate contacts GC may be buried in or extend to an upper portion of the outer electrode PO2 of the gate electrode GE. For example, the gate contacts GC may include at least one selected from metallic materials (e.g., Ti, Mo, W, Cu, Al, Ta, Ru, Ir, or Co) or metal nitrides (e.g., nitride of Ti, Mo, W, Cu, Al, Ta, Ru, Ir, or Co).

A separation pattern DB may be interposed between the first active region AR1 and a through via structure PVS which will be discussed below and between the second active region AR2 and a through via structure PVS which will be discussed below. The separation pattern DB may extend in the second direction D2. For example, the separation pattern DB may include a dielectric material. The separation pattern DB may electrically separate the single height cell from other logic cells that neighbor each other in the first direction D1.

Metal patterns MT may be provided in the third interlayer dielectric layer ILD3. Upper vias UVI may be interposed between the metal patterns MT and the gate contacts GC. The metal patterns MT may be connected through the upper vias UVI to the gate contacts GC. For example, although not shown, each of the metal pattern MT and the upper via UVI may be provided in the form of a plurality of layers, and the metal pattern MT and the upper via UVI may be alternately stacked. The metal patterns MT and the upper vias UVI may include a metallic material (e.g., Ti, Mo, W, Cu, Al, Ta, Ru, Ir, or Co).

A power delivery network layer PDN may be provided on a bottom surface of the substrate 200. The power delivery network layer PDN may include a plurality of lower wiring lines (not shown) that are connected to the first pattern T1 of the first source/drain pattern SD1 through a through via structure PVS, an upper power via UWV, an upper power line UPL, and an upper conductive contact UCA which will be discussed below. The power delivery network layer PDN may include a wiring line network for applying a source voltage. The power delivery network layer PDN may include a wiring line network for applying a drain voltage.

A through via structure PVS may penetrate or extend into the substrate 200, and may be connected to the power delivery network layer PDN. The through via structure PVS may extend along the third direction D3. For example, the through via structure PVS may penetrate or extend in the third direction D3 through or into the device isolation pattern ST, the first interlayer dielectric layer ILD1, and the second interlayer dielectric layer ILD2. The through via structure PVS may be provided on a lateral surface of the separation pattern DB. The through via structure PVS may be adjacent in the first direction D1 to each of the first region AR1 and the second active region AR2.

The through via structure PVS may include an upper through via UPV and a lower through via LPV between the upper through via UPV and the power delivery network layer PDN. The upper through via UPV may penetrate or extend into the second interlayer dielectric layer ILD2, and may extend into the first interlayer dielectric layer ILD1. The lower through via LPV may penetrate or extend into the substrate 200 and the device isolation pattern ST, and may extend into the first interlayer dielectric layer ILD1. When viewed in a direction parallel to the top surface of the substrate 200, a width of the upper through via UPV may increase in the third direction D3. When viewed in a direction parallel to the top surface of the substrate 200, a width of the lower through via LPV may decrease in the third direction D3.

The upper active contact UCA (also referred to as the upper conductive contact) may be provided on a top surface of the first pattern T1 of the first source/drain pattern SD1. The upper active contact UCA may extend along the second direction D2 from the top surface of the first pattern T1 of the first source/drain pattern SD1 to a top surface of the first pattern T1 of the second source/drain pattern SD2. The upper active contact UCA may include at least one selected from metallic materials (e.g., Ti, Mo, W, Cu, Al, Ta, Ru, Ir, or Co), metal nitrides (e.g., nitride of Ti, Mo, W, Cu, Al, Ta, Ru, Ir, or Co), or metal silicides (e.g., silicide of Ti, Mo, W, Cu, Al, Ta, Ru, or Ir).

The upper active contact UCA may be electrically and/or physically connected to the first pattern T1 of the first source/drain pattern SD1. The upper active contact UCA may be in contact with the first pattern T1 of the first source/drain pattern SD1. For example, metal silicide in the upper active contact UCA may be in contact with the first pattern T1 of the first source/drain pattern SD1. As a result, a metallic material in the upper active contact UCA may be electrically and/or physically connected to the first pattern T1 of the first source/drain pattern SD1 through metal nitride and metal silicide in the upper active contact UCA.

The upper active contact UCA may include a plurality of upper active contacts UCA that neighbor each other in the first direction D1. Each of the upper active contacts UCA may be provided on a top surface of a corresponding first pattern T1 of the first source/drain pattern SD1, and may be electrically and/or physically connected to the corresponding first pattern T1. Each of the upper active contacts UCA may be provided on a top surface of a corresponding first pattern T1 of the second source/drain pattern SD2, and may be electrically and/or physically connected to the corresponding first pattern T1.

The upper power line UPL may be provided on a top surface of the through via structure PVS. The upper power line UPL may be provided on a top surface of the upper active contact UCA. The upper power line UPL may extend along the first direction D1 from above the through via structure PVS to above the upper active contact UCA. The upper power line UPL may be electrically connected to the through via structure PVS and the upper active contact UCA through the upper power via UWV which will be discussed below. The upper power line UPL may be electrically connected through the upper power via UWV to the upper active contacts UCA that neighbor along the first direction D1. For example, the upper power line UPL may include at least one selected from metallic materials (e.g., Ti, Mo, W, Cu, Al, Ta, Ru, Ir, or Co) or metal nitrides (e.g., nitride of Ti, Mo, W, Cu, Al, Ta, Ru, Ir, or Co).

The upper power line UPL may include a plurality of upper power lines UPL that are adjacent to each other in the second direction D2 on the top surface of the through via structure PVS. Three upper power lines UPL are illustrated in figures, but the present inventive concepts are not limited thereto. The upper power lines UPL may include two or more upper power lines UPL on the top surface of the through via structure PVS.

The upper power lines UPL may extend along the first direction D1 from above one through via structure PVS to above one upper active contact UCA. The upper power lines UPL may extend along the first direction D1 from above one through via structure PVS to above each of the upper active contacts UCA that neighbor each other in the first direction D1. When viewed in plan, the upper power lines UPL may be interposed between opposite lateral surfaces S1 and S2 of the through via structure PVS. For example, one S1 of the opposite lateral surfaces S1 and S2 of the through via structure PVS may be directed in the second direction D2, and the other one S2 of the opposite lateral surfaces S1 and S2 of the through via structure PVS may be directed in a direction traverse to the second direction D2. When viewed in plan, the upper power lines UPL may be interposed between the first source/drain pattern SD1 and the second source/drain pattern SD2.

The upper power via UWV may be interposed between the upper power line UPL and the through via structure PVS and between the upper power line UPL and the upper active contact UCA. The upper power line UPL may be connected through the upper power via UWV to each of the through via structure PVS and the upper active contact UCA. For example, the upper power via UWV may include at least one selected from metallic materials (e.g., Ti, Mo, W, Cu, Al, Ta, Ru, Ir, or Co) or metal nitrides (e.g., nitride of Ti, Mo, W, Cu, Al, Ta, Ru, Ir, or Co).

The upper power via UWV may include a first upper power via UWV1 between the upper power line UPL and the through via structure PVS and a second upper power via UWV2 between the upper power line UPL and the upper active contact UCA.

The first upper power via UWV1 may include a plurality of first upper power vias UWV1 that are adjacent to each other in the second direction D2 on the top surface of the through via structure PVS. Each of the first upper power vias UWV1 may be provided below a corresponding one of the upper power lines UPL. Three first upper power lines UWV1 are illustrated in figures, but the present inventive concepts are not limited thereto. The first upper power vias UWV1 may include two or more first upper power vias UWV1 on the top surface of the through via structure PVS. For example, the number of the first upper power vias UWV1 on the top surface of the through via structure PVS may be the same as that of the upper power lines UPL on the top surface of the through via structure PVS. The through via structure PVS may be connected through the first upper power vias UWV1 to the upper power lines UPL.

The second upper power via UWV2 may include second upper power vias UWV2 that are adjacent to each other in the second direction D2 on the top surface of the upper active contact UCA. Each of the second upper power vias UWV2 may be provided below a corresponding one of the upper power lines UPL. Three second upper power lines UWV2 are illustrated in figures, but the present inventive concepts are not limited thereto. The second upper power vias UWV2 may include two or more second upper power vias UWV2 on the top surface of the upper active contact UCA. For example, the number of the second upper power vias UWV2 on the top surface of the upper active contact UCA may be the same as that of the upper power lines UPL on the top surface of the upper active contact UCA. The upper active contact UCA may be electrically connected through the second upper power vias UWV2 to the upper power lines UPL.

A backside power rail MPR may be provided in the substrate 200. The backside power rail MPR may be buried in the substrate 200. The backside power rail MPR may be provided below and vertically overlap the first source/drain pattern SD1. For example, the backside power rail MPR may not vertically overlap the second source/drain pattern SD2. The backside power rail MPR may extend along the first direction D1 below the first source/drain pattern SD1. The backside power rail MPR may extend from the single height cell into a logic cell adjacent in the first direction D1 to the single height cell. For example, the backside power rail MPR may include at least one selected from metallic materials (e.g., Ti, Mo, W, Cu, Al, Ta, Ru, Ir, or Co) or metal nitrides (e.g., nitride of Ti, Mo, W, Cu, Al, Ta, Ru, Ir, or Co).

A backside conductive structure BCS may be interposed between the second pattern T2 of the first source/drain pattern SD1 and the backside power rail MPR. The backside conductive structure BCS may electrically connect the second pattern T2 of the first source/drain pattern SD1 to the backside power rail MPR. For example, the backside conductive structure BCS may be in contact with a bottom surface of the second pattern T2 of the first source/drain pattern SD1 and with a top surface of the backside power rail MPR. The backside conductive structure BCS may not be provided below the first pattern T1 of the first source/drain pattern SD1. The backside conductive structure BCS may be provided in plural. The plurality of backside conductive structures BCS may be interposed between the second patterns T2 of the first source/drain patterns SD1 and the backside power rail MPR.

The backside conductive structure BCS may include a backside conductive contact BCA below the first source/drain pattern SD1 and a backside power via MPV between the backside conductive contact BCA and the backside power rail MPR. The backside conductive contact BCA and the backside power via MPV may be in contact with each other, while having a step difference therebetween. Each of the backside conductive contact BCA and the backside power via MPV may include at least one selected from metallic materials (e.g., Ti, Mo, W, Cu, Al, Ta, Ru, Ir, or Co) or metal nitrides (e.g., nitride of Ti, Mo, W, Cu, Al, Ta, Ru, Ir, or Co).

With reference to FIGS. 2A, 2B, 2C, 3A, and 3B, based on connection relationships between various components of the present inventive concepts, the following will describe how the single height cell and its neighboring other logic cells are transferred with voltages that are applied through various components from the power delivery network layer PDN.

Referring to FIGS. 1, 2A, 2B, 2C, and 3A, the single height cell may include one power gating cell including a power gating circuit PGC. For example, the power gating circuit PGC may be provided on the first active region AR1. The power gating circuit PGC may provide a power to other logic cell adjacent to the first active region AR1.

The power gating circuit PGC may be electrically connected to the power delivery network layer PDN that provides a global power voltage V_{GP}. The power gating circuit PGC may include a first connection line PA1, a power gating transistor PTR, and a second connection line PA2. The global power voltage V_{GP} applied from the power delivery network layer PDN may be transmitted through the first connection line PA1 to the power gating transistor PTR.

A gate voltage V_{G} may be applied to the power gating transistor PTR. The gate voltage VG may correspond to a voltage for turning on the power gating transistor PTR. For example, as the power gating transistor PTR is provided with a voltage equal to or greater than the gate voltage V_{G}, the power gating transistor PTR may be turned on, and thus the first connection line PA1 and the second connection line PA2 may be connected to each other. Therefore, a power voltage V_{DD} may be transmitted to the second connection line PA2. The power voltage V_{DD} may be transmitted through the second connection line PA2 to logic cells that neighbor a power gating cell.

For another example, as the power gating transistor PTR is provided with a voltage less than the gate voltage V_{G}, the power gating transistor PTR may be turned off, and thus the first connection line PA1 and the second connection line PA2 may not be electrically connected to each other. Therefore, the power voltage V_{DD} may not be transmitted to the second connection line PA2, and the second connection line PA2 may be electrically floated.

According to the present inventive concepts, a semiconductor device may include a power gating cell. The power gating circuit PGC in the power gating cell may selectively transmit the power voltage V_{DD} to the second connection line PA2, and may selectively electrically float the second connection line PA2. Thus, the power gating cell may selectively transmit the power voltage V_{DD} only to a logic cell that requires power supply. Accordingly, a power usage of the semiconductor device may be minimized to improve a power consumption of the semiconductor device.

Referring to FIGS. 2A, 2B, 2C, and 3B, the global power voltage V_{GP} may be applied from the power delivery network layer PDN. As discussed above, the power delivery network layer PDN may be connected to the through via structure PVS. Thus, the global power voltage V_{GP} may be transmitted to the through via structure PVS. As previously described, the upper power lines UPL may be electrically connected to the power delivery network layer PDN through the first upper power vias UWV1 and the through via structure PVS. Therefore, the global power voltage V_{GP} may be transmitted to the upper power lines UPL.

As mentioned above, the upper power lines UPL may be electrically connected through the second upper power vias UWV2 to the upper active contact UCA. As seen from the above, the upper active contact UCA may be connected to the first pattern T1 of the first source/drain pattern SD1. For example, the upper power lines UPL may be connected through the second upper power vias UWV2 and the upper active contact UCA to the first pattern T1 of the first source/drain pattern SD1. Therefore, the global power voltage V_{GP} may be transmitted to the first pattern T1 of the first source/drain pattern SD1.

The first connection line PA1 discussed with reference to FIG. 3A may include the through via structure PVS, the first upper power vias UWV1, the upper power lines UPL, the second upper power vias UWV2, the upper active contact UCA, and the first pattern T1 of the first source/drain pattern SD1.

The power gating transistor PTR discussed with reference to FIG. 3A may include the first pattern T1 and the second pattern T2 of the first source/drain pattern SD1, the first channel pattern CH1 between the first and second patterns T1 and T2 of the first source/drain pattern SD1, and the gate electrode GE that runs across the first channel pattern CH1.

When the gate electrode GE is provided with a voltage equal to or greater than the gate voltage V_{G}, the power gating transistor PTR of FIG. 3A may be turned on, and thus the first pattern T1 of the first source/drain pattern SD1 may be electrically connected through the first channel pattern CH1 to the second pattern T2 of the first source/drain pattern SD1. As a result, the global power voltage V_{GP} transmitted through the first connection line PA1 may be transferred to the second pattern T2 of the first source/drain pattern SD1. The power voltage V_{DD} may be defined to refer to a voltage transmitted to the second pattern T2 of the first source/drain pattern SD1.

The backside power rail MPR may be connected through the backside conductive structure BCS to the second pattern T2 of the first source/drain pattern SD1. Therefore, the power voltage V_{DD} may be transmitted to the backside power rail MPR.

The second connection line PA2 discussed with reference to FIG. 3A may be constituted by the second pattern T2 of the first source/drain pattern SD1, the backside conductive structure BCS, and the backside power rail MPR.

As described above, the backside power rail MPR may extend along the first direction D1 below the first source/drain pattern SD1. Thus, the power voltage V_{DD} may be transmitted through the backside power rail MPR in the single height cell to other logic cells that are adjacent in the first direction D1 to the single height cell.

According to the present inventive concepts, the power delivery network layer PDN may be connected to the first connection line PA1 (i.e., the through via structure PVS, the first upper power vias UWV1, the upper power lines UPL, the second upper power vias UWV2, the upper active contact UCA, and the first pattern T1 of the first source/drain pattern SD1). Thus, the first connection line PA1 may transmit the global power voltage V_{GP} applied from the power delivery network layer PDN. In addition, when the power gating transistor PTR is turned on, the first connection line PA1 may be connected to the second connection line PA2 (e.g., the second pattern T2 of the first source/drain pattern SD1, the backside conductive structure BCS, and the backside power rail MPR). Therefore, the power voltage V_{DD} may be transmitted to the second connection line PA2, and may be transferred through the second connection line PA2 to other logic cells. As each of the first and second connection lines PA1 and PA2 is partially buried in the substrate 200, there may be an increase in the degree of freedom of arrangement of components for driving the power gating cell. Accordingly, it may be easy to design a semiconductor device.

In addition, a plurality of upper power lines UPL and a plurality of upper power vias UWV may be provided on the through via structure PVS and the upper active contact UCA. The upper via structure PVS may be connected to the upper active contact UCA through the plurality of upper power lines UPL and the plurality of upper power vias UWV. Therefore, the first connection line PA1 may have a reduced electrical resistance compared to a case where the through via structure PVS is connected to the upper active contact UCA through one upper power line UPL and one upper power via UWV. As a result, a voltage applied from the power delivery network layer PDN may be sufficiently transmitted through the first connection line PA1 to the second connection line PA2. Accordingly, a semiconductor device may improve in electrical properties.

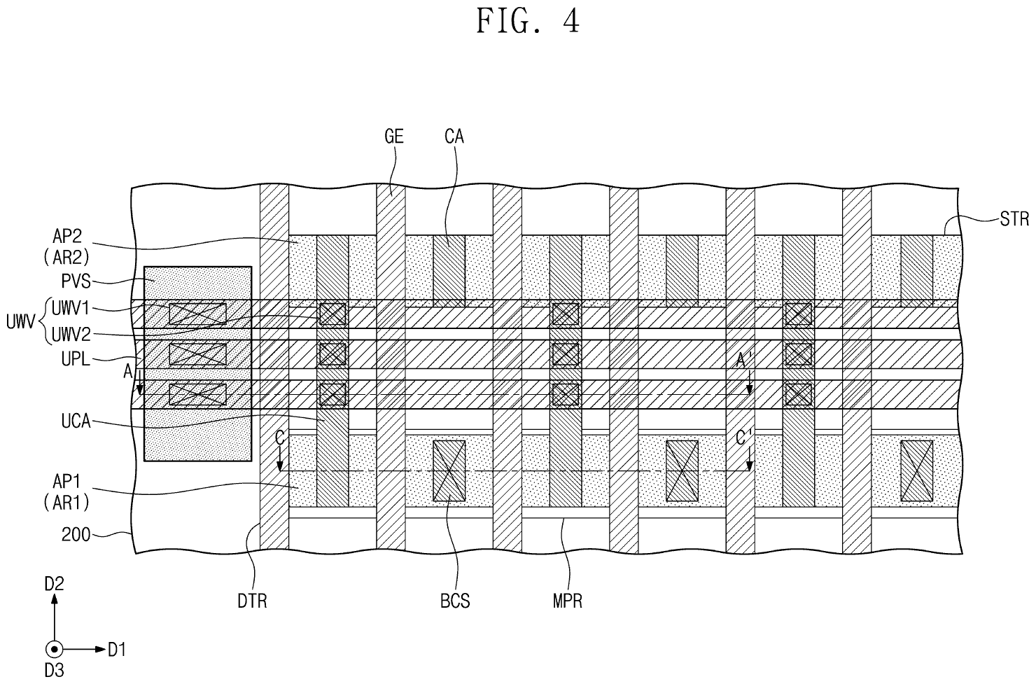

With reference to FIGS. 4, 5A, 5B, 6, and 7, the following will describe semiconductor devices according to some embodiments of the present inventive concepts. For brevity of description, an explanation of components repetitive to those discussed above will be omitted, and a difference thereof will be discussed in detail.

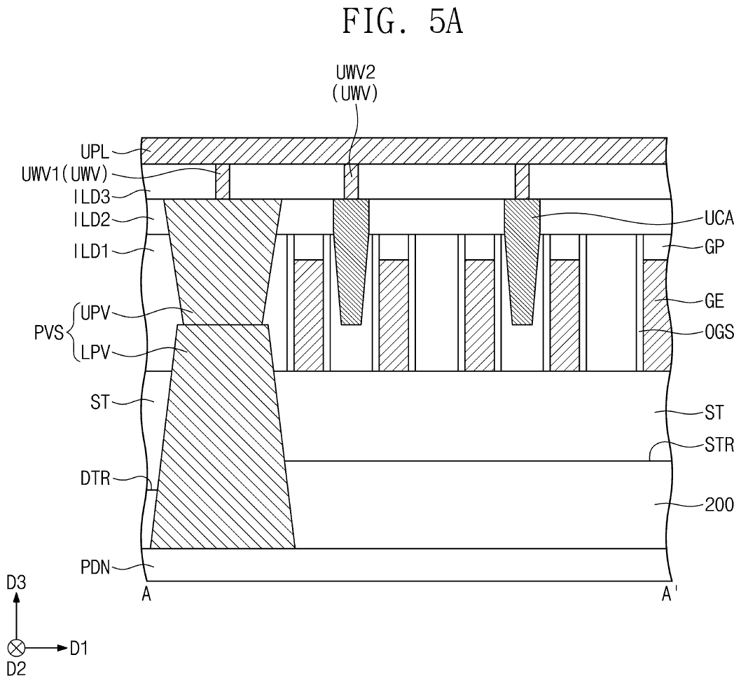

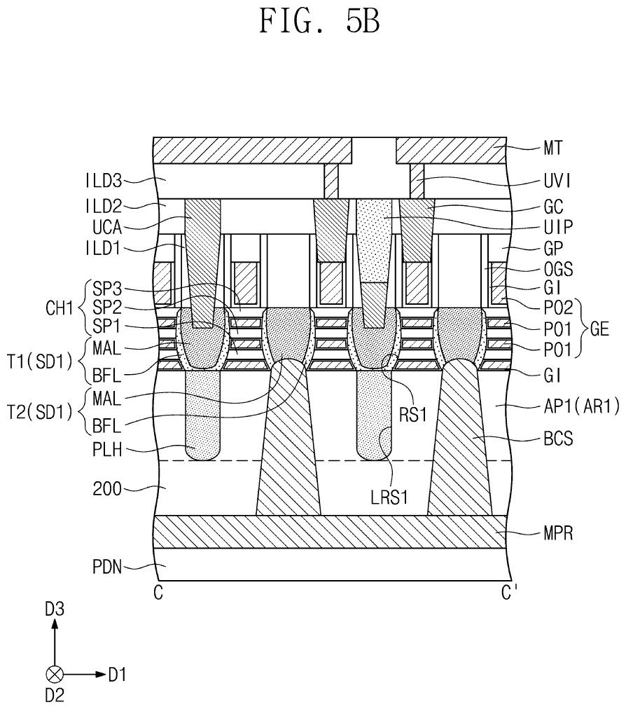

FIG. 4 illustrates a plan view showing a semiconductor device according to some embodiments of the present inventive concepts. FIGS. 5A and 5B illustrate cross-sectional views respectively taken along lines A-A′ and C-C′ of FIG. 4.

Referring to FIGS. 4, 5A, and 5B, different from that discussed with reference to FIGS. 1 and 2A to 2C, the backside conductive contact BCA may be omitted. Thus, the backside power via MPV discussed with reference to FIGS. 1, 2A, 2B, and 2C may extend from the top surface of the backside power rail MPR to the bottom surface of the second pattern T2 of the first source/drain pattern SD1, and may constitute the backside conductive structure BCS. A lateral surface of the backside conductive structure BCS may have no step difference.

Different from that discussed with reference to FIGS. 1, 2A, 2B, and 2C, the separation pattern DB may be omitted, and may be replaced with the gate electrode GE and the gate capping pattern GP.

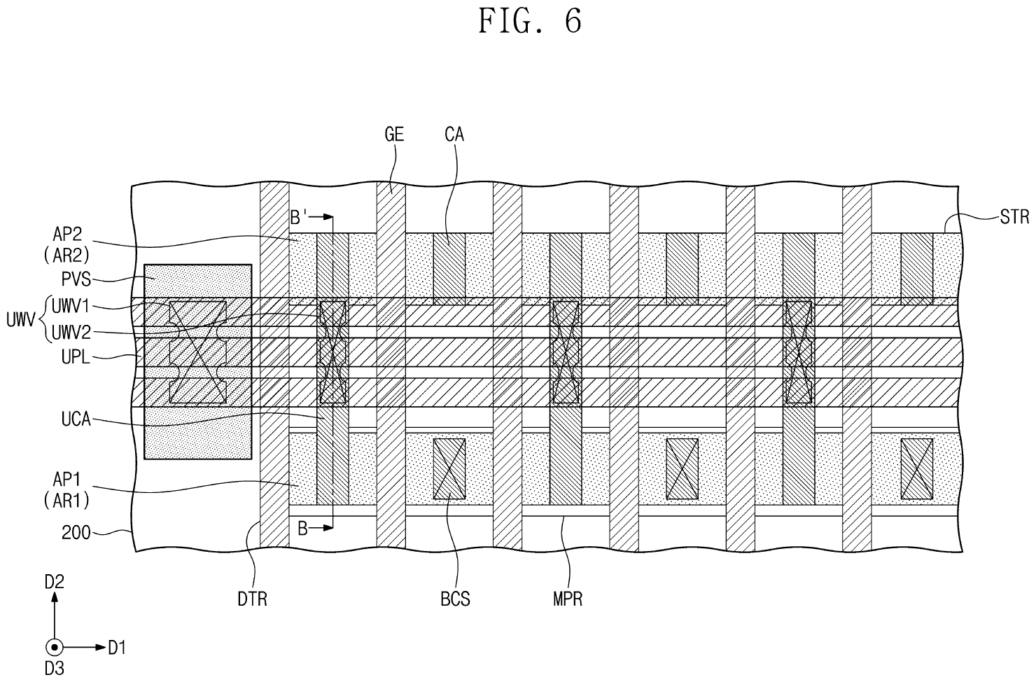

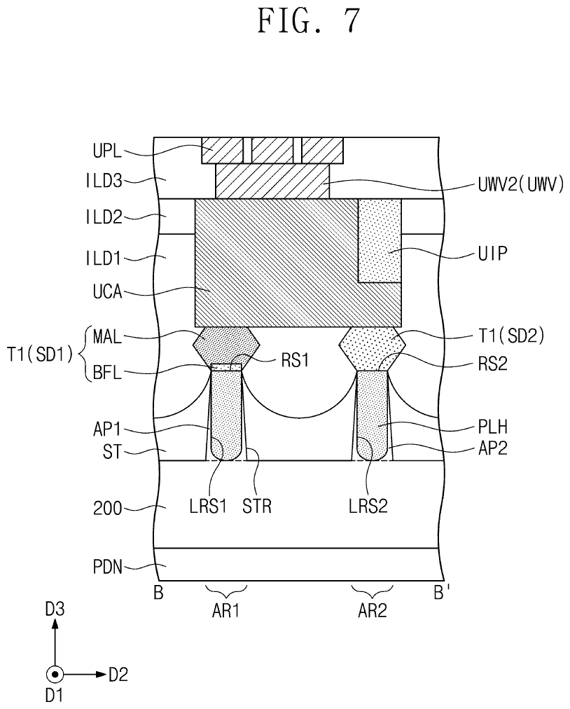

FIG. 6 illustrates a plan view showing a semiconductor device according to some embodiments of the present inventive concepts. FIG. 7 illustrates a cross-sectional view taken along line B-B′ of FIG. 6.

Referring to FIGS. 6 and 7, one first upper power via UWV1 may be provided on the top surface of the through via structure PVS. One first upper power via UWV1 may be electrically and/or physically connected to the upper power lines UPL. Thus, the upper power lines UPL may be electrically connected through one first upper power via UWV1 to the through via structure PVS. For example, one first upper power via UWV1 may contact and vertically overlap the upper power lines UPL. The first upper power via UWV1 may have a lateral surface whose portion has a profile concave toward the first upper power via UWV1. The lateral surface of the first upper power via UWV1 may have a wavy profile.

The second upper power vias UWV2 may be correspondingly provided on the top surfaces of the upper active contacts UCA that neighbor in the first direction D1. For example, one second upper power via UWV2 may be provided on the top surface of one upper active contact UCA. The upper power lines UPL may be electrically connected through one second upper power via UWV2 to one upper active contact UCA. Thus, the upper power lines UPL may be electrically connected through one second upper power via UWV2 to the upper active contact UCA. The second upper power via UWV2 may have a lateral surface whose features are the same as or similar to those of the lateral surface of the first upper power via UWV1.

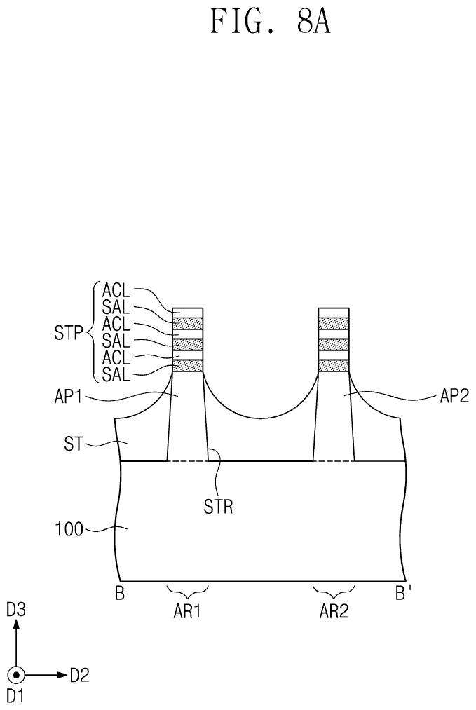

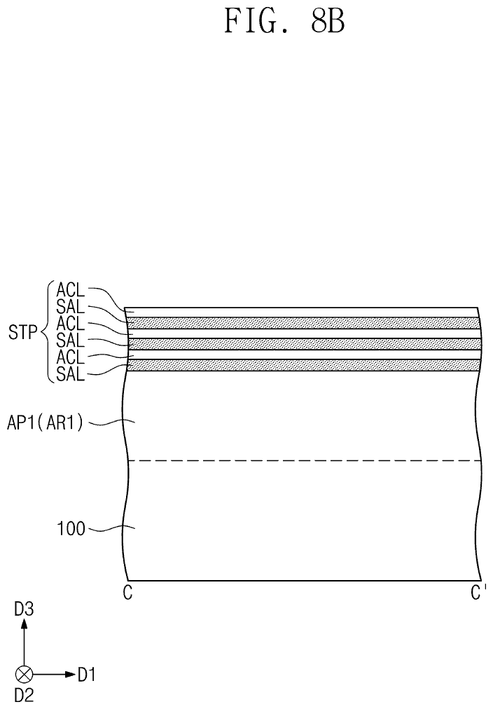

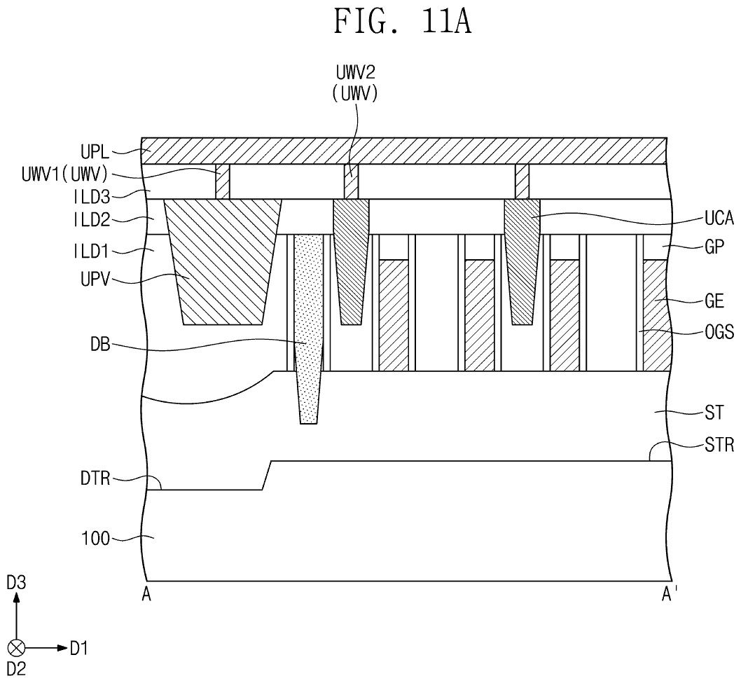

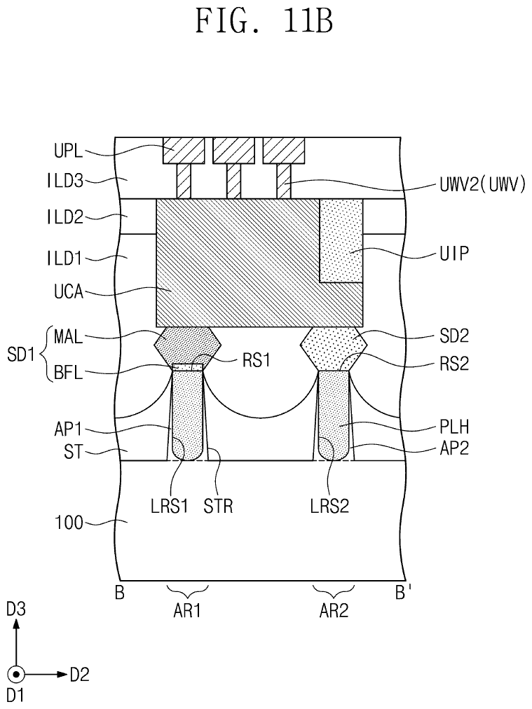

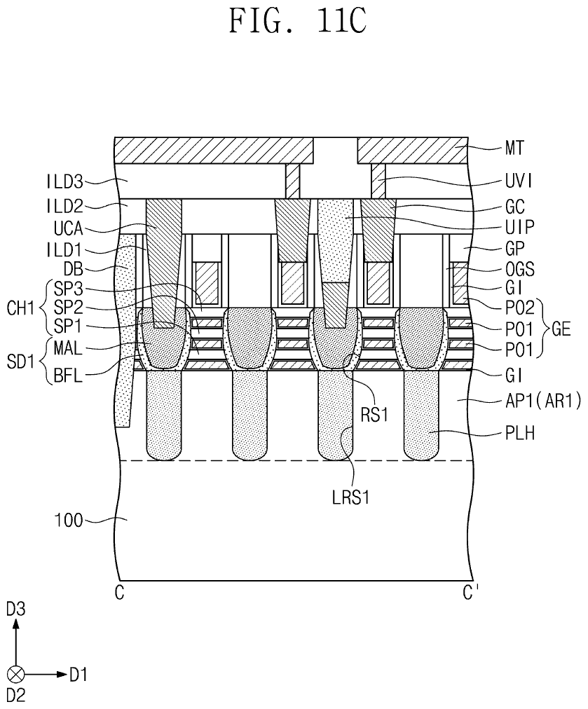

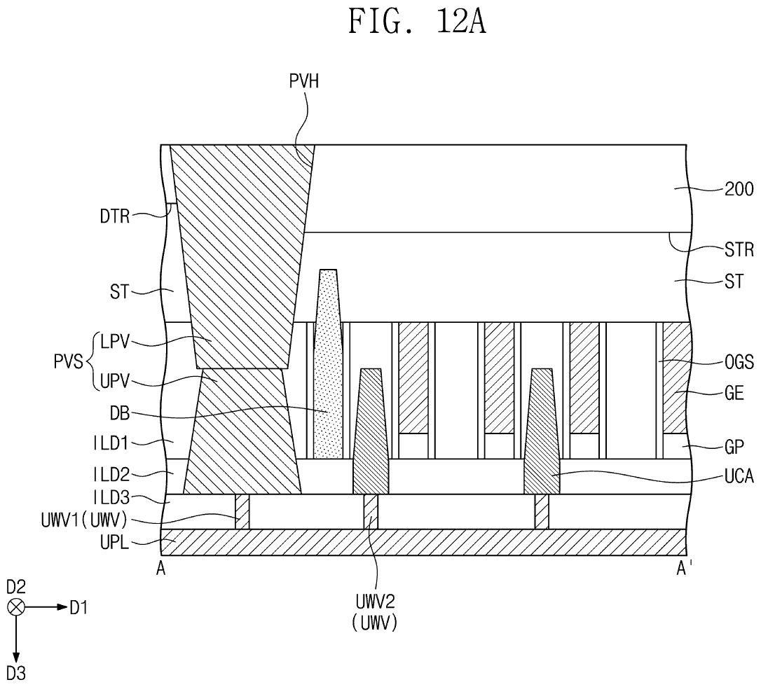

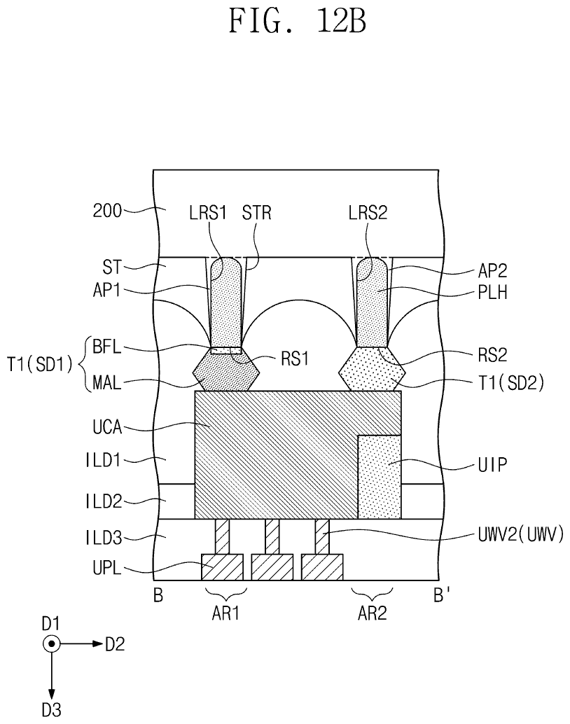

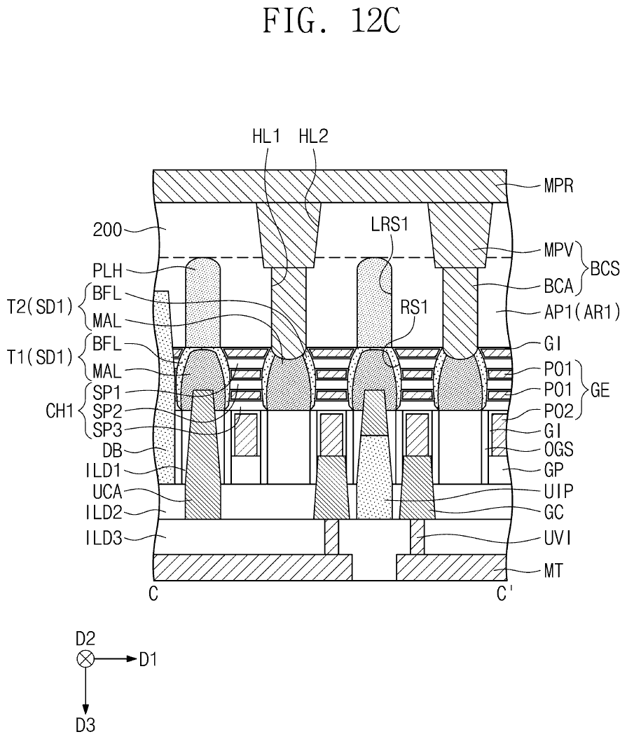

FIGS. 8A, 8B, 9A, 9B, 10, 11A, 11B, 11C, 12A, 12B, and 12C illustrate cross-sectional views showing a method of fabricating a semiconductor device according to some embodiments of the present inventive concepts. FIGS. 11A and 12A illustrate cross-sectional views taken along line A-A′ of FIG. 1. FIGS. 8A, 9A, 11B, and 12B illustrate cross-sectional views taken along line B-B′ of FIG. 1. FIGS. 8B, 9B, 10, 11C, and 12C illustrate cross-sectional views taken along line C-C′ of FIG. 1.

Referring to FIGS. 1, 8A, and 8B, a semiconductor substrate 100 may be provided which includes a first active region AR1 and a second active region AR2. For example, the semiconductor substrate 100 may be a semiconductor substrate including a semiconductor material, such as a monocrystalline silicon substrate, a silicon-germanium substrate, or silicon-on-insulator (SOI) substrate. Stack patterns STP may be formed on the first active region AR1 and the second active region AR2. For example, the formation of the stack patterns STP may include alternately stacking semiconductor layers ACL and sacrificial layers SAL on the semiconductor substrate 100, forming mask patterns (not shown) that extend in a first direction D1, and using the mask patterns as an etching mask to perform a patterning process. During the patterning process, a portion of the semiconductor substrate 100 may be removed, and device isolation trenches STR may be formed to define a first active pattern AP1 and a second active pattern AP2. For example, when the device isolation trenches STR are formed, a substrate trench DTR may also be formed. Device isolation patterns ST may be formed to fill the device isolation trenches STR and the substrate trench DTR.

The sacrificial layers SAL may include a material having an etch selectivity with respect to the semiconductor layers ACL. Thus, even when the sacrificial layers SAL are removed in a process which will be discussed below, the semiconductor layers ACL may not be removed or may be slightly removed. For example, the semiconductor layers ACL may include one of silicon (Si), germanium (Ge), or silicon-germanium (SiGe), and the sacrificial layers SAL may include another of silicon (Si), germanium (Ge), or silicon-germanium (SiGe).

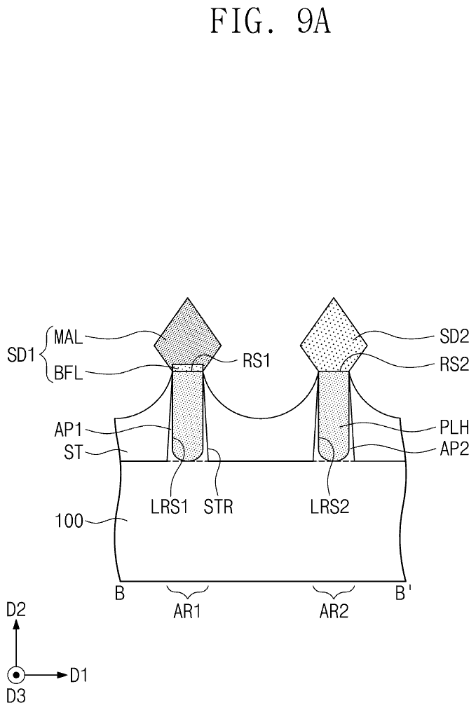

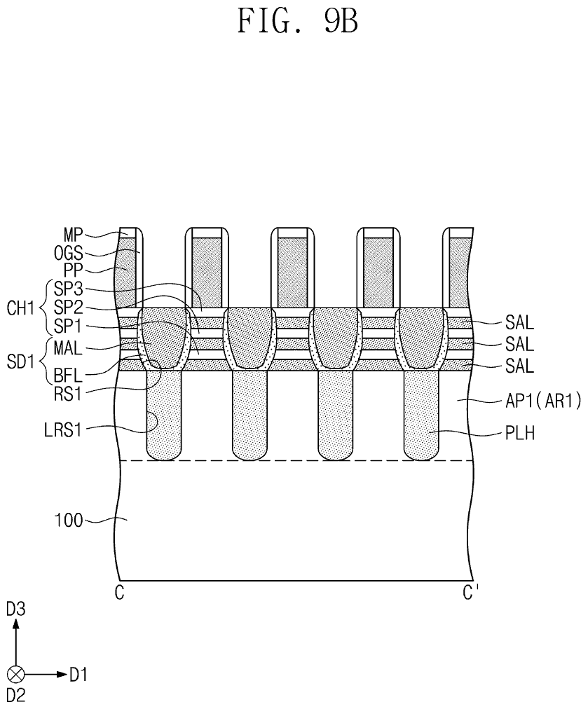

Referring to FIGS. 1, 9A, and 9B, sacrificial patterns PP may be formed to extend along a second direction D2 on the semiconductor substrate 100. The sacrificial patterns PP may be formed to cover or overlap top surfaces of the device isolation patterns ST and also to cover or overlap lateral and top surfaces of the stack patterns STP. For example, the formation of the sacrificial patterns PP may include forming a sacrificial layer (not shown) on a front surface of the semiconductor substrate 100, forming hardmask patterns MP on the sacrificial layer, and using the hardmask patterns MP as an etching mask to remove a portion of the sacrificial layer to form the sacrificial patterns PP. The sacrificial pattern PP may include polysilicon. Afterwards, outer gate spacers OGS may be formed on lateral surfaces of the sacrificial patterns PP.

First recesses RS1 may be formed in the stack pattern STP on the first active pattern AP1. Second recesses RS2 may be formed in the stack pattern STP on the second active pattern AP2. For example, the first recess RS1 and the second recess RS2 may be formed by using the hardmask patterns MP as an etching mask to remove a portion of the stack pattern STP.

The first recesses RS1 may separate the semiconductor layers ACL on the first active pattern AP1 into first channel patterns CH1 that are spaced apart from each other in the first direction D1. The second recesses RS2 may separate the semiconductor layers ACL on the second active pattern AP2 into second channel patterns (not shown) that are spaced apart from each other in the first direction D1. Each of the first channel pattern CH1 and the second channel pattern may include first, second, and third semiconductor patterns SP1, SP2, and SP3.

A first lower recess LRS1 may be formed below the first recess RS1. A second lower recess LRS2 may be formed below the second recess RS2. A sacrificial contact pattern PLH may be formed through selective epitaxial growth (SEG) in which the semiconductor substrate 100 is used as a seed, thereby filling each of the first lower recess LRS1 and the second lower recess LRS2.

First source/drain patterns SD1 may be formed in the first recesses RS1. The first source/drain patterns SD1 may be formed through selective epitaxial growth (SEG) in which the sacrificial contact pattern PLH and the first, second, and third semiconductor patterns SP1, SP2, and SP3 on the first active region AR1 are used as seeds.

For example, during the formation of the first source/drain pattern SD1, impurities (e.g., boron, gallium, or indium) may be in-situ implanted to allow the first source/drain pattern SD1 to have a p-type conductivity. In some embodiments, after the formation of the first source/drain pattern SD1, the impurities may be implanted into the first source/drain pattern SD1.

Second source/drain patterns SD2 may formed in the second recesses RS2. The second source/drain patterns SD2 may be formed through selective epitaxial growth (SEG) in which the sacrificial contact pattern PLH and the first, second, and third semiconductor patterns SP1, SP2, and SP3 on the second active region AR2 are used as seeds.

For example, during the formation of the second source/drain pattern SD2, impurities (e.g., phosphorus, arsenic, or antimony) may be in-situ implanted to allow the second source/drain pattern SD2 to have an n-type conductivity type. In some embodiments, after the formation of the second source/drain pattern SD2, the impurities may be implanted into the second source/drain pattern SD2.

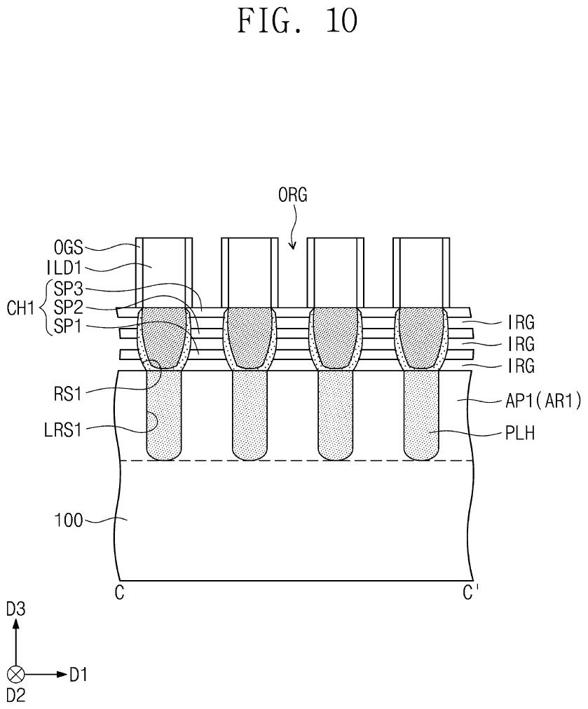

Referring to FIGS. 1 and 10, a first interlayer dielectric layer ILD1 may be formed to cover or overlap the first source/drain pattern SD1, the second source/drain pattern (see SD2 of FIG. 9A), the hardmask patterns MP, and the outer gate spacers OGS. After that, the first interlayer dielectric layer ILD1 may be removed on top surfaces of the sacrificial patterns PP. In the removal process, the hardmask patterns MP may also be removed, and the sacrificial patterns PP may be exposed.

Thereafter, the exposed sacrificial patterns PP may be removed, and an outer region ORG may be formed on a region where the sacrificial patterns PP are removed. The outer region ORG may outwardly expose the first channel pattern CH1, the second channel pattern CH2, and the sacrificial layers SAL.

The exposed sacrificial layers SAL may be selectively removed. In this stage, the first, second, and third semiconductor patterns SP1, SP2, and SP3 may not be removed or may be slightly or partially removed due to a high etch selectivity of the sacrificial layers SAL.

Inner regions IRG may be formed on regions where the sacrificial layers SAL are removed. For example, the inner regions IRG may be formed between the first, second, and third semiconductor patterns SP1, SP2, and SP3.

A gate dielectric pattern GI may be formed in each of the inner regions IRG and the outer region ORG. The gate dielectric pattern GI may be formed to surround each of the first, second, and third semiconductor patterns SP1, SP2, and SP3.

Referring to FIGS. 1 and 11A, 11B, and 11C, a gate electrode GE may be formed on the gate dielectric pattern GI. The gate electrode GE may include an inner electrode PO1 formed in each of the inner regions IRG and an outer electrode PO2 formed in the outer region ORG. A gate capping pattern GP may be formed on the outer electrode PO2 of the gate electrode GE.

A separation pattern DB may be formed to penetrate or extend into the first interlayer dielectric layer ILD1. For example, as discussed with reference to FIGS. 4, 5A, 5B, 6, and 7, the formation of the separation pattern DB may be omitted.

A second interlayer dielectric layer ILD2 may be formed on the first interlayer dielectric layer ILD1 and the gate capping pattern GP. An upper power via UWV, upper active contacts UCA, and active contacts CA may be formed to penetrate or extend into the second interlayer dielectric layer ILD2 to extend into the first interlayer dielectric layer ILD1. For example, the upper power via UWV, the upper active contacts UCA, and the active contacts CA may be formed simultaneously with each other.

An upper portion of each of the upper active contacts UCA and the active contacts CA may be partially removed, and upper dielectric patterns UIP may be formed to partially or completely fill the removed portions.

Gate contacts GC may be formed to penetrate or extend into the second interlayer dielectric layer ILD2 and the gate capping pattern GP and to connect with the gate electrodes GE.

A third interlayer dielectric layer ILD3 may be formed on the second interlayer dielectric layer ILD2. Upper power lines UPL, metal patterns MT, upper power vias UWV, and upper via UVI may be formed in the third interlayer dielectric layer ILD3.

Referring to FIGS. 1, 12A, 12B, and 12C, after a back-end-of-line (BEOL) process is terminated, the semiconductor substrate 100 discussed with reference to FIGS. 8A and 8B may be turned upside down. Thus, a bottom surface of the semiconductor substrate 100 may be exposed. As the semiconductor substrate 100 is turned upside down, in the following description with reference to FIGS. 12A, 12B, and 12C, the expression “top surface” and “upper portion” may respectively refer to “bottom surface” and “lower portion” of the fabricated semiconductor device discussed with reference to FIGS. 2A, 2B, and 2C, and the expression “bottom surface” and “lower portion” may respectively refer to “top surface” and “upper portion” of the fabricated semiconductor device fabricated with reference to FIGS. 2A, 2B, and 2C.

The exposed surface of the semiconductor substrate 100 may undergo a planarization process to reduce a thickness of the semiconductor substrate 100. For example, during the planarization process, the semiconductor substrate 100 may be fully or partially removed.

Dielectric layers (not shown) including a dielectric material may be formed to form a removed region of the semiconductor substrate 100. A substrate 200 may be constituted by the dielectric layers and a remaining portion of the semiconductor substrate 100.

The substrate 200 may undergo a patterning process to form a through via hole PVH. A lower through via LPV may be formed to partially or completely fill the through via hole PVH. An upper through via UPV and the lower through via LPV may constitute a through via structure PVS.

The sacrificial contact patterns PLH may be removed on the second patterns T2 of the first source/drain patterns SD1, and thus first holes HL1 may be formed. A backside conductive contact BCA may be formed to partially or completely fill each of the first holes HL1.

The substrate 200 may undergo a patterning process to form a second hole HL2 on each of the first holes HL1. A backside power via MPV may be formed to partially or completely fill the second hole HL2. The backside conductive contact BCA and the backside power via MPV may constitute a backside conductive structure BCS.

In some embodiments, the formation of the first hole HL1 may be omitted, and the second hole HL2 may be formed to expose a top surface of the second pattern T2 of the first source/drain pattern SD1. Then, the backside power via MPV may be formed to partially or completely fill the second hole HL2, and may constitute the backside conductive structure BCS. As a result, it may be possible to form the backside conductive structure BCS discussed with reference to FIGS. 4, 5A, and 5B.

A backside power rail MPR may be formed on a top surface of the backside conductive structure BCS.

Referring back to FIGS. 1, 2A, 2B, and 2C, a power delivery network layer PDN may be formed on a bottom surface of the substrate 200.

According to the present inventive concepts, a semiconductor device may include a power gating cell. Thus, the power gating cell may selectively transmit a power voltage only to a logic cell that requires power supply. Accordingly, a power usage of the semiconductor device may be minimized to improve a power consumption of the semiconductor device.

According to the present inventive concepts, some wiring lines for driving the power gating cell may be buried in a substrate. There may thus be an increase in the degree of freedom of arrangement of components for driving the power gating cell. Accordingly, it may be easy to design the semiconductor device.

In addition, a through via structure may be connected to an upper active contact through a plurality of upper power vias and a plurality of upper power lines. Therefore, the power gating circuit may have a reduced electrical resistance compared to a case where the through via structure is connected to the upper active contact through one upper power line and one upper power via. As a result, a voltage applied from a power delivery network layer may be sufficiently transmitted through the power gating circuit to a peripheral logic cell. Accordingly, the semiconductor device may improve in electrical properties.

Although some embodiments of the present invention have been discussed with reference to accompanying figures, it will be understood that various changes in form and details may be made therein without departing from the spirit and scope of the present invention. It therefore will be understood that the embodiments described above are just illustrative but not limitative in all aspects.

What is claimed is:

1. A semiconductor device, comprising:
a power delivery network layer on a bottom surface of a substrate;
a gate electrode on the substrate;
a first source/drain pattern on the substrate, the first source/drain pattern including a first pattern and a second pattern that are spaced apart from each other with the gate electrode therebetween;
a through via structure that extends into the substrate and is electrically connected to the power delivery network layer;
an upper conductive contact on the first pattern of the first source/drain pattern;
an upper power line that extends on the through via structure and on the upper conductive contact;
a backside power rail that extends along an extension direction of the upper power line and is on an opposite side of the first source/drain pattern from the upper power line; and
a backside conductive structure between the backside power rail and the second pattern of the first source/drain pattern.

2. The semiconductor device of claim 1, wherein the upper power line includes a plurality of upper power lines that are adjacent to each other in a direction orthogonal to the extension direction of the upper power line,
wherein the upper power lines are electrically connected to the through via structure and the upper conductive contact.

3. The semiconductor device of claim 2, wherein, in plan view, the upper power lines are between opposite lateral surfaces of the through via structure.

4. The semiconductor device of claim 2, further comprising:
a plurality of first upper power vias on a top surface of the through via structure,
wherein the through via structure is electrically connected by the first upper power vias to the upper power lines.

5. The semiconductor device of claim 2, further comprising:
a plurality of second upper power vias on and in contact with a top surface of the upper conductive contact,
wherein the upper conductive contact is electrically connected by the second upper power vias to the upper power lines.

6. The semiconductor device of claim 2, further comprising:
a first upper power via between the through via structure and at least one of the upper power lines,
wherein the through via structure is electrically connected by the first upper power via to the at least one of the upper power lines.

7. The semiconductor device of claim 2, further comprising:
a second upper power via between the upper conductive contact and at least one of the upper power lines,
wherein the upper conductive contact is electrically connected by the second upper power via to the at least one of the upper power lines.

8. The semiconductor device of claim 1, further comprising:
a first upper power via between the through via structure and the upper power line and a second upper power via between the upper conductive contact and the upper power line,
wherein the through via structure is electrically connected to the upper power line by the first upper power via, and the upper conductive contact is electrically connected to the first pattern of the first source/drain pattern.

9. The semiconductor device of claim 1, further comprising:
a first channel pattern between the first pattern of the first source/drain pattern and the second pattern of the first source/drain pattern,
wherein the first pattern of the first source/drain pattern is electrically connected by the first channel pattern to the second pattern of the first source/drain pattern.

10. The semiconductor device of claim 1, wherein the second pattern of the first source/drain pattern is electrically connected by the backside conductive structure to the backside power rail.

11. The semiconductor device of claim 1, further comprising:
a pair of second source/drain patterns that are spaced apart from each other with the gate electrode therebetween, wherein the upper conductive contact extends from a top surface of the first source/drain pattern to a top surface of a first one of the pair of second source/drain patterns; and
an active contact on a top surface of a second one of the pair of second source/drain patterns.

12. The semiconductor device of claim 1, wherein the through via structure is electrically connected to the backside power rail by the upper power line, the upper conductive contact, the first pattern and the second pattern of the first source/drain pattern, and/or the backside conductive structure.

13. A semiconductor device, comprising:
a power delivery network layer on a bottom surface of a substrate;
a gate electrode on the substrate;
a first source/drain pattern on the substrate, the first source/drain pattern including a first pattern and a second pattern that are spaced apart from each other with the gate electrode therebetween;
a through via structure that extends into the substrate and is electrically connected to the power delivery network layer;
an upper conductive contact on the first pattern of the first source/drain pattern;
a plurality of upper power lines, ones of which extend on the through via structure and/or on the upper conductive contact, wherein the upper power lines are electrically connected to the through via structure and the upper conductive contact;
a backside power rail that extends along an extension direction of the upper power lines and is on an opposite side of the first source/drain pattern from the upper power lines; and
a backside conductive structure between the backside power rail and the second pattern of the first source/drain pattern.

14. The semiconductor device of claim 13, wherein, in plan view, the upper power lines are between opposite lateral surfaces of the through via structure.

15. The semiconductor device of claim 13, further comprising:
a plurality of first upper power vias on a top surface of the through via structure,
wherein the through via structure is electrically connected by the first upper power vias to the upper power lines.

16. The semiconductor device of claim 13, further comprising:
a plurality of second upper power vias on and in contact with a top surface of the upper conductive contact,
wherein the upper conductive contact is electrically connected by the second upper power vias to the upper power lines.

17. The semiconductor device of claim 13, further comprising:
a first upper power via between the through via structure and the upper power lines and a second upper power via between the upper conductive contact and the upper power lines,
wherein the through via structure is electrically connected to the upper power lines by the first upper power via, and the upper conductive contact is electrically connected to the first pattern of the first source/drain pattern.

18. The semiconductor device of claim 13, wherein the upper conductive contact includes a plurality of upper conductive contacts that are adjacent to one another along the extension direction of the upper power lines,
wherein the upper power lines are electrically connected to corresponding ones of the upper conductive contacts.

19. A semiconductor device, comprising:
a power delivery network layer on a bottom surface of a substrate;
a gate electrode on the substrate;
a first source/drain pattern on the substrate, the first source/drain pattern including a first pattern and a second pattern that are spaced apart from each other with the gate electrode therebetween;
a first channel pattern between the first pattern of the first source/drain pattern and the second pattern of the first source/drain pattern, wherein the first channel pattern comprises a plurality of semiconductor patterns that are spaced apart from each other in a direction perpendicular to the substrate;
a through via structure that extends into the substrate and is electrically connected to the power delivery network layer;
a plurality of upper conductive contacts on the first pattern of the first source/drain pattern, wherein the plurality of upper conductive contacts are adjacent to one another in a first direction parallel to a top surface of the substrate;
a plurality of upper power lines that extend along the first direction on the through via structure and on the upper conductive contacts and that electrically connect the through via structure and the upper conductive contacts;
a backside power rail that extends along the first direction and is on an opposite side of the first source/drain pattern from the plurality of upper power lines; and
a backside conductive structure between the backside power rail and the second pattern of the first source/drain pattern.

20. The semiconductor device of claim 19, further comprising:
a first upper power via between the through via structure and the upper power lines and a second upper power via between the upper conductive contacts and the upper power lines,
wherein the through via structure is electrically connected to the backside power rail by the upper power lines, the first upper power via, the second upper power via, the upper conductive contacts, the first pattern of the first source/drain pattern, the semiconductor patterns, the second pattern of the first source/drain pattern, and/or the backside conductive structure.
